(19) United States
(12) Patent Application Publication
(10) Pub. No.: US 2008/0265385 A1
(43) Pub. Date: Oct. 30, 2008

(54) Semiconductor package using copper wires and wire bonding method for the same

(75) Inventors: Han-Lung Tsai, Taichung (TW); Chih-Ming Huang, Hsinchu Hsein (TW); Cheng-Hsu Hsiao, Taichung (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 12/215,543

(22) Filed: Jun. 27, 2008

(30) Foreign Application Priority Data
Apr. 11, 2007 (TW) 096112654
Jun. 29, 2007 (TW) 096123660

(51) Int. Cl. H01L 21/60; H01L 23/495

(52) U.S. Cl. 257/673; 438/123; 257/E23.031; 257/E21.506

(57) ABSTRACT

A semiconductor package using copper wires and a wire bonding method for the same are proposed. The package includes a carrier having fingers and a chip mounted on the carrier. The method includes implanting stud bumps on the fingers of the carrier and electrically connecting the chip and the carrier by copper wires with one ends of the copper wires being bonded to bond pads of the chip and the other ends of the copper wires being bonded to the stud bumps on the carrier. The implanted stud bumps on the carrier improve bondability of the copper wires to the carrier and thus prevent stitch lift. With good bonding, residues of copper wires left behind after a bonding process have even tail ends and uniform tail length to enable fabrication of solder balls of uniform size, thereby eliminating a conventional step of implanting stud bumps on the bond pads of chips and preventing ball lift from occurring.

### FIELD OF THE INVENTION

The invention relates to a semiconductor package and a wire bonding method for the same. More particularly, the invention relates to a semiconductor package using copper wires for electrically connecting a carrier to a chip mounted on the carrier and a wire bonding method for the same.

### BACKGROUND OF THE INVENTION

In conventional semiconductor packages, gold wires are generally used to electrically connect a chip to a chip carrier such as a leadframe or a substrate, since gold wires can form good bonding with a silver-coated layer on fingers of the leadframe or a Ni/Au layer on fingers of the substrate, a good bonding quality between the gold wires and the fingers can be ensured. Due to high cost of gold, however, there is a trend in the art to migrate from using gold wires to using other materials such as Copper (Cu). But copper cannot form good bonding with the silver-coated layer on the fingers of a leadframe or the Ni/Au layer on the fingers of a substrate, which thus may lead to short tail of the stitch ends of copper wires bonded to the fingers and further lead to uneven tail ends and inconsistent tail length of copper wires remained beyond the capillary after a bonding process, thus adversely affecting formation of free air balls (FAB) for a subsequent wire bonding process and resulting in nonuniform size of free air balls. Nonuniform size of the free air balls can easily result in poor bonding between the free air balls and the bond pads of the chip, thus adversely and ultimately causing a ball lift problem in the fabrication process.

As depicted in FIG. 3A, a good bonding is formed between a stitch end 300 of a conventional Au wire 30 and a Ni/Au layer formed on the finger 310 of a substrate 31 and thus stitch lift between the Au wire 30 and the finger 310 is prevented from occurring. Moreover, after the Au wire 30 is bonded to the finger 310, the stitch end 300 does not have short tail, which enables residue of the Au wire 30 remained beyond the capillary M after a bonding process to have an even tail end 301 with a uniform length h, such that the free air balls 302 of uniform size can be formed before subsequent wire bonding process, thus ensuring good bonding quality between the Au wires and the bond pads.

In the case of using copper wires as shown in FIG. 3B, since the copper wire 30′ does not have good bonding with the Ni/Au layer formed on the finger 310′ of a substrate 31, after the stitch end 300′ of the copper wire 30′ is bonded to the finger 310′, short tail can easily occur to the stitch end 300′, thus causing residue of the copper wire 30′ remained beyond the capillary M after a bonding process to have an uneven tail end 301′ with length h′. As a result, the free air balls 302′ of different sizes are formed before subsequent wire-bonding process, which easily results in ball lift problem of the free air balls 302′ bonded to the bond pads 330′ of the chip 33′.

To overcome the problems described above, as shown in FIG. 4, U.S. Patent Publication No. 20040072396 discloses a method of implanting Au stud bumps 43 on bond pads 421 of a chip 42 for allowing free air balls 402 of copper wires 40 to be bonded onto the Au stud bumps 43 so as to form good bonding therebetween, thus enhancing bonding quality between the bond pads 421 and the copper wires 40 and effectively preventing the problem of ball lift from occurring. However, the problems of stitch lift or short tail of the stitch ends 400 bonded to the fingers 411 still exist since the copper wire 40 cannot form good bonding with the silver-coated layer or the Ni/Au layer formed on the fingers 411 of a leadframe or a substrate 41, which further adversely affects uniformity of the free air balls to be formed subsequently.

Therefore, it is highly desirable and beneficial to develop a semiconductor package using copper wires and a wire bonding method for the same that can overcome the conventional problems of ball lift and stitch lift so as to enhance bonding reliability of copper wires.

### SUMMARY OF THE INVENTION

In light of the drawback associated with the conventional techniques as described above, an objective of the present invention is to provide a semiconductor package using copper wires and a wire bonding method for the same, which enhances bondability of copper wires on fingers of a carrier by implanting on the fingers of the carrier Au stud bumps that have good bonding with the copper wires, thereby overcoming the stitch lift problem of the prior art.

Another objective of the present invention is to provide a semiconductor package using copper wires and a wire bonding method for the same, which prevents the ball lift problem from occurring to copper wires bonded to bond pads of a chip by implanting on fingers of a carrier Au stud bumps that have good bonding with the copper wires.

Another objective of the present invention is to provide a semiconductor package using copper wires and a wire bonding method for the same. By implanting Au stud bumps on fingers of a carrier, wherein the Au stud bumps have good bonding with copper wires, residues of copper wires remained beyond the capillary after a bonding process have an even tail end and uniform tail length, and thus enabling formation of uniform free air balls before subsequent wire bonding process so as to form good bonding between the copper wires and bond pads of a chip without the need of implanting Au stud bumps on the bond pads of the chip.

In accordance with the foregoing and other objectives, a semiconductor package using copper wires according to the present invention comprises a carrier with a plurality of fingers, wherein the carrier may be a leadframe or a substrate; a plurality of stud bumps made of such as Au implanted on the fingers of the carrier; a chip mounted on the carrier, the active surface of the chip having a plurality of bond pads; a plurality of copper wires, wherein each of the copper wires has one end bonded to each of the bond pads of the chip and the other end bonded to each of the stud bumps on the carrier such that the chip can be electrically connected to the carrier through the copper wires; and an encapsulant formed on the carrier for encapsulating the chip, the copper wires and the stud bumps.

The present invention further provides a wire bonding method applied to the semiconductor package using copper wires described above. The method comprises the steps of: providing a carrier such as a leadframe or a substrate with a chip mounted thereon, wherein the carrier is provided with a plurality of fingers and a plurality of stud bumps is implanted on the fingers; and bonding one end of each of the copper wires to each of bond pads of the chip and bonding the other end of each of the copper wires to each of the stud bumps on the fingers, thereby electrically connecting the chip to the carrier through the copper wires.

Accordingly, the semiconductor package using copper wires and the wire bonding method for the same according to the present invention is characterized in that Au stud bumps that have good bonding with copper wires are implanted on fingers of a carrier so as to enhance bondability of the copper wires to the fingers and overcome the stitch lift problem of the prior art. With good bonding and enhanced bondability, residues of copper wires remained beyond a capillary after a bonding process have even tail ends and uniform tail length, which in turn facilitates fabrication of solder balls of uniform size before subsequent wire bonding process and thus eliminates the necessity to implant Au stud bumps on the bond pads of a chip and meanwhile overcomes the ball lift problem of the prior art, thereby enhancing the bonding reliability of copper wires. Therefore, the present invention offers advantages over the prior art and has high industrial applicability.

### BRIEF DESCRIPTION OF THE DRAWINGS

Other features and advantages of the invention will be apparent from the following detailed description when read in conjunction with the accompanying drawings, in which

FIG. 1 illustrates a cross-sectional view of a semiconductor package in accordance with the present invention;

FIGS. 2A and 2B are diagrams illustrating steps of a wire-bonding method in accordance with the present invention;

FIG. 3A (PRIOR ART) illustrates a cross-sectional view of a conventional semiconductor package using Au wires;

FIG. 3B (PRIOR ART) illustrates a cross-sectional view of a conventional semiconductor package using Cu wires; and

FIG. 4 (PRIOR ART) illustrates a cross-sectional view of a semiconductor package disclosed by U.S. Patent Publication No. 20040072396.

### DETAILED DESCRIPTION OF THE PREFERRED EMBODIMENTS

The present invention is described in the following with specific embodiments, so that one skilled in the pertinent art can easily understand other advantages and effects of the present invention from the disclosure of the invention. The present invention may also be implemented and applied according to other embodiments, and the details may be modified based on different views and applications without departing from the spirit of the invention.

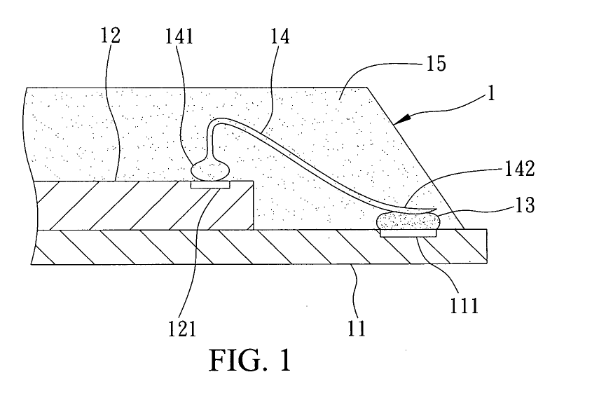

FIG. 1 illustrates a semiconductor package using Cu wires according to the present invention, which comprises a substrate 11, a chip 12 mounted on the substrate 11, a plurality of Au stud bumps 13 implanted on the substrate 11, a plurality of copper wires 14 for electrically connecting the substrate 11 and the chip 12, and an encapsulant 15 formed on the substrate 11 for encapsulating the chip 12, the Au stud bumps 13 and the copper wires 14.

The substrate 11 has a plurality of fingers 111 formed thereon such that the Au stud bumps 13 can be implanted on the fingers 111, thus allowing stitch end 142 of the copper wire 14 to be stitch bonded to the Au stud bump 13. The substrate 11 may be a conventional epoxy resin substrate, a polyimide substrate, a glass substrate or a ceramic substrate. Since manufacture of the substrate 11 is well known in the art, there will be no further description about the formation of the fingers 111 on the substrate 11 for the sake of brevity. Also, It should be noted that the use of the substrate 11 as a carrier for carrying the chip 12 is only exemplary and the invention is not limited thereto. For instance, a leadframe may be employed for carrying the chip 12.

The chip 12 has a plurality of bond pads 121 formed thereon for allowing solder ball 141 formed on one end of the copper wire 14 to be bonded thereon such that after the two ends of the copper wire 14 are bonded to the finger 111 of the substrate 11 and the bond pad 121 of the chip 12 respectively, the chip 12 can be electrically connected to the substrate 11 through the copper wires 14.

Since the molding process for forming the encapsulant 15 and the die bond process for bonding the chip 12 to the substrate 11 are well known in the art, detailed descriptions of the both processes will be purposely omitted herein for the sake of brevity. The efficacy of the semiconductor package I will be described in more detail in the following wire bonding method proposed by the invention.

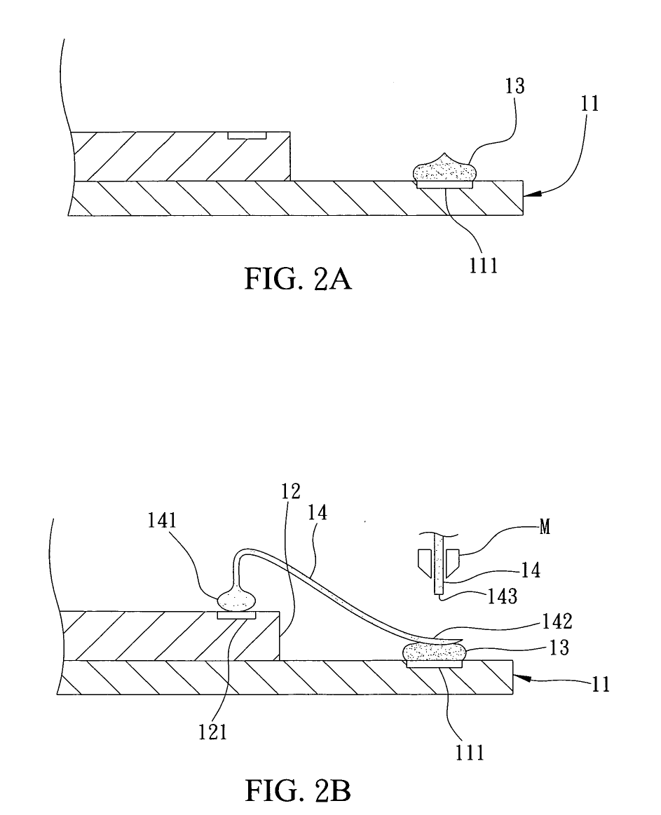

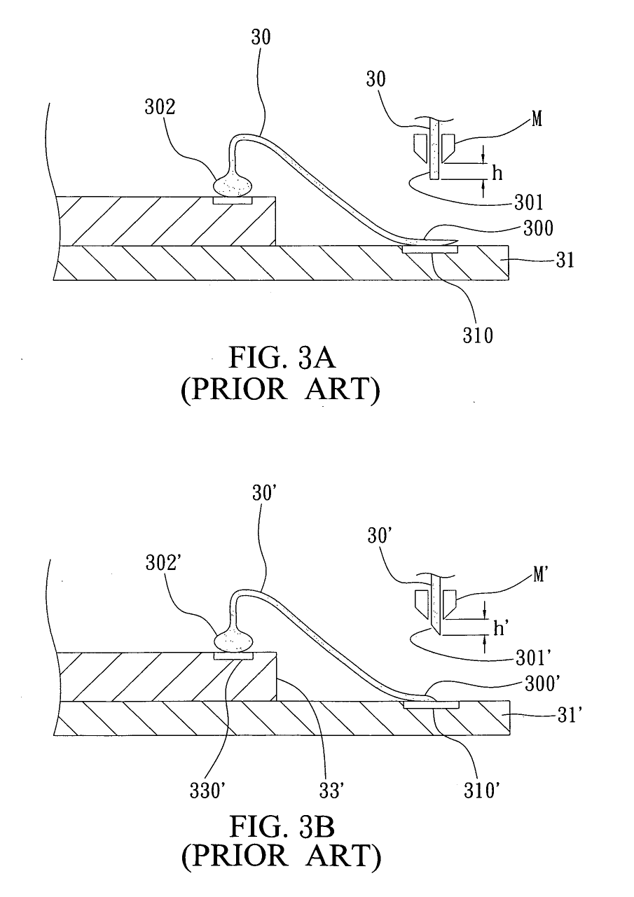

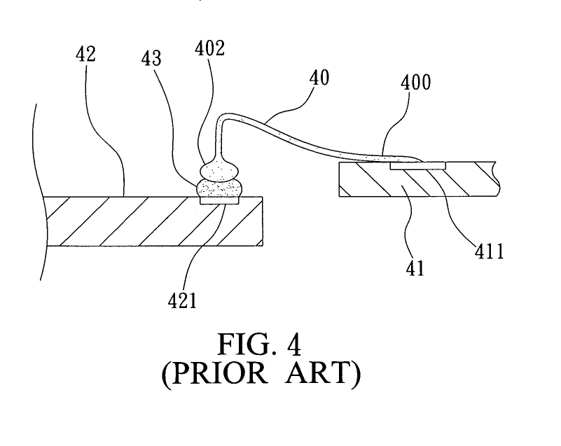

As shown in FIGS. 2A and 2B, the wire-bonding method of the invention is applicable for manufacturing the semiconductor package using copper wires either in the process of batch production or piece by piece.

FIG. 2A depicts the step of implanting a plurality of Au stud bumps 13 on the fingers 111 of the substrate 11. Subsequently, FIG. 2B depicts the step of forming a solder ball 141 (Free Air Ball, FAB) on one end of a copper wire 14 by a wire bonding machine, the solder ball 141 being bonded to the bond pad 121 of the chip 12 by an ultrasonic thermal press or ultrasonic bonding technique. Thereafter, the capillary M of the wire bonding machine (not shown) is moved upward to a predetermined height and is then pulled downward to position of a finger 111 of the substrate 11 so as to form a wire loop of the copper wire 14. Until the capillary M is moved to the position of the finger 111, the capillary M is pressed down such that the copper wire 14 can be bonded to the Au stud bump 13 formed on the finger 111 by means of stitch bond. The copper wire 14 forms a good bonding with the Au stud bump 13 and an arc-shaped stitch end 142 is formed, thereby accomplishing the bonding between the copper wire 14 and the bond pad 121 of the chip 12, and the bonding between the copper wire 14 and the finger 111 of the substrate 11.

Since the Au stud bumps 13 on the fingers 111 have good bonding with the stitch ends 142 of the copper wires 14, the conventional problem of short tail of the stitch ends 142 is prevented, and accordingly stitch lift of the stitch ends 142 from the Au stud bumps 13 caused by short tail is avoided. With good bonding, residues of copper wires 143 remained beyond the capillary after a bonding process have even tail end and uniform tail length, which in turn facilitates formation of solder balls 141 of uniform size and eliminates the necessity to implant Au stud bumps on the bond pads of the chip and meanwhile solves the ball lift problem as encountered in the prior art, thereby enhancing bondability between the copper wires and the chip as well as the carrier and ensuring reliability of the semiconductor package.

It will be understood that the invention may be embodied in other specific forms without departing from the spirit or central characteristics thereof. The present examples and embodiments, therefore, are to be considered in all respects as illustrative and not restrictive, and the invention is not to be limited to the details given herein.

What is claimed is:

1. A semiconductor package using copper wires, comprising:
a carrier with a plurality of fingers;
a chip mounted on the carrier and having a plurality of bond pads;
a plurality of stud bumps implanted on the fingers of the carrier;
a plurality of copper wires, wherein each of the copper wires has one end bonded to each of the bond pads of the chip and the other end bonded to each of the stud bumps on the carrier, and the chip is electrically connected to the carrier through the copper wires; and
an encapsulant formed on the carrier to encapsulate the chip, the copper wires and the stud bumps.

2. The semiconductor package using copper wires of claim 1, wherein the stud bumps are made of Au.

3. The semiconductor package using copper wires of claim 1, wherein a solder ball is formed on one end of each of the copper wires to be bonded to each of the bond pads, and the other end of each of the copper wires is bonded to each of the stud bumps by stitch bonding.

4. The semiconductor package using copper wires of claim 1, wherein the carrier is a leadframe.

5. The semiconductor package using copper wires of claim 1, wherein the carrier is a substrate.

6. A wire bonding method for a semiconductor package using copper wires, comprising the steps of:
implanting a plurality of stud bumps on a plurality of fingers of a carrier; and
bonding one end of each of the copper wires to each of bond pads of a chip mounted on the carrier, and bonding the other end of each of the copper wires to each of the stud bumps on the carrier, and the chip is electrically connected to the carrier through the copper wires.

7. The wire bonding method of claim 6, wherein the stud bumps are made of Au.

8. The wire bonding method of claim 6, wherein a solder ball is formed on one end of each of the copper wires to be bonded to each of the bond pads, and the other end of each of the copper wires is bonded to each of the stud bumps by stitch bonding.

9. The wire bonding method of claim 6, wherein the carrier is a leadframe.

10. The wire bonding method of claim 6, wherein the carrier is a substrate.
